(19) United States
(12) Patent Application Publication
(10) Pub. No.: US 2025/0197708 A1
(43) Pub. Date: Jun. 19, 2025

(54) COOLANT FOR IMMERSION COOLING SYSTEM AND IMMERSION COOLING SYSTEM INCLUDING THE SAME

(71) Applicant: GS CALTEX CORPORATION, Seoul (KR)

(72) Inventors: Dae-Hyun KIM, Seoul (KR); Woo-Kyun SYNN, Seoul (KR); Rae-Wook CHO, Seoul (KR)

(21) Appl. No.: 18/829,871

(22) Filed: Sep. 10, 2024

(30) Foreign Application Priority Data
Dec. 15, 2023 (KR) 10-2023-0183295
Jul. 11, 2024 (KR) 10-2024-0091956

(51) Int. Cl. C09K 5/10; C08F 10/14; H01B 3/20; H05K 7/20

(52) U.S. Cl. CPC C09K 5/10; C08F 10/14; H01B 3/20; H05K 7/20236

(57) ABSTRACT

Disclosed are a coolant for an immersion cooling system and an immersion cooling system including the same. More specifically, the coolant for the immersion cooling system includes cooling oil as polyalphaolefin (PAO) heat transfer oil having a low-viscosity and electrical insulation properties and high heat transfer efficiency.

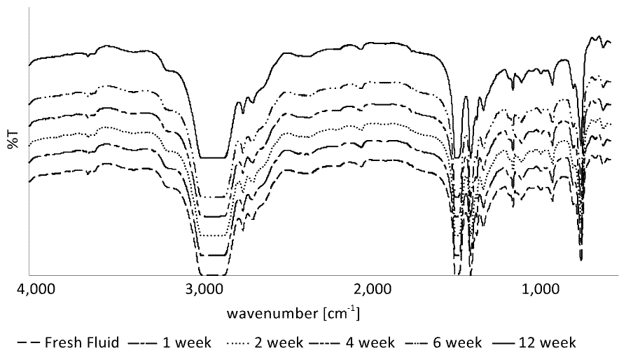

### CROSS-REFERENCE TO RELATED APPLICATION

This application claims priority from Korean Patent Applications No. 10-2023-0183295 filed on Dec. 15, 2023 and No. 10-2024-0091956 filed on Jul. 11, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to a coolant for an immersion cooling system and an immersion cooling system including the same. More specifically, the present disclosure relates to a coolant for an immersion cooling system, comprising cooling oil as polyalphaolefin (PAO) heat transfer oil having a low-viscosity and electrical insulation properties and high heat transfer efficiency, and an immersion cooling system including the same.

### Description of Related Art

With the recent rapid development of the information technology (IT) industry and the creation of vast amounts of data, the number of data centers as a building or facility that stores therein and manages digital data and provides a server computer for storing IT infrastructure and network lines to is increasing.

As advanced data services such as cloud and artificial intelligence (AI) technology develop, an amount of power used in the data centers increases. Accordingly, the heat generation phenomenon from the data center is becoming more severe. When the server in the data center is overloaded and overheated, the computer's heat sink or cooling fan cannot sufficiently cool the central processing unit (CPU) or graphic processing unit (GPU). As a result, the server may malfunction or go down, and furthermore, excessive heat generation may lead to a fire problem in the data center.

Accordingly, in most of data centers, separate constant temperature and humidity equipment is installed and controlled in a server room where a server rack is installed. However, in a large-scale data center, a larger number of constant temperature and humidity equipment is needed because an amount of heat generated therefrom is greater. When the larger number of the constant temperature and humidity equipment is installed, not only does the cost increase rapidly, but it also consumes money and energy to operate the larger number of the constant temperature and humidity equipment.

In addition to the computer server, storages, network switches, and batteries used in various energy storage systems (ESS) as used in the data center generate a lot of heat during operation. A separate cooling system should be installed to strongly cool this heat.

In addition, there is a conventional system for comparing the temperature and humidity of the inside thereof with the temperature and humidity of the outside air out of the data center and introducing the outside air to the inside thereof or circulating the inside air based on the comparing result, thereby cooling the inside of the data center. However, this system is not able to cool the data center efficiently, and it is difficult for the system to precisely control temperature and humidity depending on the external environment.

Recently, an immersion cooling scheme of directly immersing the electronic devices that generate heat, such as servers and batteries in the data center into an electrically insulating (non-conductive) liquid coolant that does not conduct electricity, has been emerging. The immersion cooling scheme has the advantage of being able to reduce energy consumption compared to existing schemes using the air-based cooling scheme, thereby increasing energy efficiency, preventing the inflow of contaminants in the air, and simplifying thermal design to reduce the number of operating parts. In order to implement an excellent cooling system using the immersion cooling scheme, an important technical task is to develop liquid coolant for immersion that has electrical insulation properties and high heat transfer efficiency.

### SUMMARY

A purpose of the present disclosure is to provide a coolant for an immersion cooling system containing polyalphaolefin (PAO) heat transfer oil having a low viscosity, and high heat transfer efficiency and an immersion cooling system containing the same.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

To achieve the above purpose, according to one aspect of the present disclosure, coolant for an immersion cooling system may be provided, the coolant comprising: polyalphaolefin (PAO) cooling oil polymerized via oligomerization of C5 to C15 alpha olefin monomers (α-olefin monomers), wherein the polyalphaolefin cooling oil has: a kinematic viscosity at 40° C. lower than 10.0 cst; a density at 20° C. of 800 kg/m³ or lower; a specific heat capacity at 40° C. of 1.5 kJ/Kg·K or greater; and a thermal conductivity at 40° C. of 0.10 W/m·k or greater.

In accordance with some embodiments of the coolant for the immersion cooling system, a flash point of the polyalphaolefin cooling oil may be in a range of 120 to 300° C.

In accordance with some embodiments of the coolant for the immersion cooling system, the polyalphaolefin cooling oil may be polymerized via oligomerization of C8 to C12 alpha olefin monomers.

In accordance with some embodiments of the coolant for the immersion cooling system, an appearance of the polyalphaolefin cooling oil may have a bright and clear color.

In accordance with some embodiments of the coolant for the immersion cooling system, the coolant for the immersion cooling system may further contain at least one additive selected from an antioxidant, a defoamer, and a corrosion inhibitor.

In accordance with some embodiments of the coolant for the immersion cooling system, the polyalphaolefin cooling oil may be contained at 99.0 to 99.9% by weight based on 100% by weight of the coolant for the immersion cooling system, wherein the at least one additive may be contained at 0.1 to 1.0% by weight based on 100% by weight of the coolant for the immersion cooling system.

According to another aspect of the present disclosure, an immersion cooling system including the coolant for the immersion cooling system as described above may be provided.

The polyalphaolefin (PAO) cooling oil according to the present disclosure is a heat transfer oil and has high thermal conductivity and low viscosity, and thus has greatly improved heat transfer efficiency, and exhibits excellent properties suitable for use as the coolant for the immersion cooling system.

The polyalphaolefin (PAO) cooling oil according to the present disclosure has excellent insulation properties and a high flash point. Thus, when the polyalphaolefin (PAO) cooling oil according to the present disclosure is contained in the coolant for the immersion cooling system, it may ensure safety against various safety accidents and fires, and has a good appearance of a bright and clear color.

In addition to the above-mentioned effects, the specific effects of the present disclosure are described below while describing the specific details for carrying out the present disclosure.

### BRIEF DESCRIPTIONS OF DRAWINGS

The sole FIGURE is a graph showing change in chemical properties as evaluated in Experimental Example 5 using Fourier transform infrared spectroscopy in accordance with the present disclosure. In the sole FIGURE, the horizontal axis represents a wavenumber (cm⁻¹), and a vertical axis represents absorbance (% T).

### DETAILED DESCRIPTIONS

The above-mentioned purposes, features, and advantages are described in detail below, and accordingly, those skilled in the art in the technical field to which the present disclosure belongs will be able to easily implement the technical ideas of the present disclosure.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, “including”, “contain”, “containing”, etc. when used in this specification, specify the presence of the stated features, integers, operations, elements, and/or components, but do not preclude the presence or addition of one or more other features, integers, operations, elements, components, and/or portions thereof.

In descriptions of temporal relationships, for example, temporal precedent relationships between two events such as “after”, “subsequent to”, “before”, etc., another event may occur therebetween unless “directly after”, “directly subsequent” or “directly before” is not indicated.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

The coolant for the immersion cooling system according to an embodiment of the present disclosure includes polyalphaolefin (PAO) cooling oil. The polyalphaolefin cooling oil may be polymerized via oligomerization of C5 to C15 alpha-olefin monomers, for example, via oligomerization of C8 to C12 alpha olefin monomers. More specifically, the polyalphaolefin cooling oil may be polymerized via oligomerization of C10 alpha olefin monomers. Alpha olefin as a monomer used in synthesizing the polyalphaolefin in accordance with the present disclosure is an olefin having a double bond at an alpha position. A molecular weight of the polyalphaolefin cooling oil may be determined depending on the number of carbons of the alpha olefin monomer, and thus the viscosity thereof may be adjusted based on the number of carbons of the alpha olefin monomer.

The reason why the polyalphaolefin-based oil is selected as the cooling oil in accordance with the present disclosure is that the viscosity of the polyalphaolefin-based oil may be adjusted to be lower, compared to the mineral or paraffin-based immersion coolant oils that have been used previously, and the polyalphaolefin-based oil may be easily synthesized using the monomers.

The immersion cooling oil should have electrical insulation properties, have a high flash point, and secure a heat transfer coefficient. In accordance with the present disclosure, a relationship between four factors for determining the heat transfer coefficient: density, thermal conductivity, specific heat capacity, and kinematic viscosity and the heat transfer coefficient is summarized as Relationship 1 as set forth below.

### Relationship 1:

$$κ ∝ \frac{ρ \times λ \times Cp}{ν}$$

In the Relationship 1, k represents the heat transfer coefficient, ρ represents the density, λ represents the thermal conductivity, Cp represents the specific heat capacity, and ν represents the kinematic viscosity.

As may be identified from Relationship 1 as set forth above, in order to improve the heat transfer coefficient, the kinematic viscosity (ν) should be lowered, and a material with high thermal conductivity (λ), high density, and high specific heat capacity should be required. Based on a result of evaluating physical properties of major candidate materials and of predicting the heat transfer coefficient based on the evaluated physical properties, it was identified that the low viscosity among the four factors had the greatest influence on the heat transfer coefficient. Thus, the kinematic viscosity and the thermal conductivity of the polyalphaolefin oil in accordance with the present disclosure was controlled to develop coolant with a high heat transfer coefficient.

Therefore, the polyalphaolefin cooling oil according to the present disclosure preferably may have the kinematic viscosity lower than 10.0 cst at 40° C., for example, 9.0 cst or lower, for example, 8.0 cst or lower, for example, 7.0 cst or lower, for example, 6.0 cst or lower, and for example, 5.0 cst or lower. In the present disclosure, “kinematic viscosity” is based on 40° C. and is measured according to the ASTM D 445/D 7042 method.

Furthermore, the polyalphaolefin cooling oil according to the present disclosure may have the thermal conductivity of 0.10 W/m·k or greater at 40° C., preferably, in a range of 0.10 to 0.15 W/m·k, for example, in a range of 0.12 to 0.14 W/m·k. In the present disclosure, the thermal conductivity is based on 40° C. and is measured according to the ASTM D 7896 method. In consideration of that the thermal conductivity of air used in a conventional data center cooling system is in a range of 0.020 to 0.03 W/m·k, the immersion cooling oil according to the present disclosure has high thermal conductivity and may exhibit excellent properties which may allow the immersion cooling oil to be suitable for use as immersion coolant.

The density (ρ) of the polyalphaolefin cooling oil according to the present disclosure may be 800 kg/m³ or lower at 20° C., for example, in a range of 600 to 800 kg/m³. In the present disclosure, the density is measured according to the ASTM D 7042 method.

The specific heat capacity (Cp) of the polyalphaolefin cooling oil according to the present disclosure may be equal to or greater than 1.5 kJ/Kg·K based on 40° C., preferably, in a range of 1.5 to 3.5 kJ/Kg·K, for example, in a range of 2.0 to 3.0 kJ/Kg·K. In the present disclosure, the specific heat capacity is measured according to the ASTM E 1269 method.

The flash point of the polyalphaolefin cooling oil according to the present disclosure is preferably in a range of 120 to 300° C., preferably, 130 to 250° C., preferably 140 to 220° C., and more preferably 150 to 200° C. Considering that the flash point of gasoline as a commonly used oil is about −42° C., and that of diesel as a commonly used oil is in a range of 52 to 96° C., the flash point of the polyalphaolefin cooling oil according to the present disclosure is at a fairly high level, thereby preventing heat generation and resulting safety accidents in the data center.

The lower the acidity of the polyalphaolefin cooling oil according to the present disclosure, the less likely it is to affect an immersion target. Thus, it is preferable that the acid number (AN) thereof is 0.01 mg KOH/g or lower.

The appearance of the polyalphaolefin cooling oil according to the present disclosure is measured according to the ASTM D 5386 method and exhibits a clear and bright color.

The polyalphaolefin cooling oil according to the present disclosure has a breakdown voltage of about 40 kV as measured according to the ASTM D 149 method. The volume resistivity of the polyalphaolefin cooling oil according to the present disclosure as measured according to the ASTM D 991 method is about 1.0×10¹³ Ω·cm. Thus, the polyalphaolefin cooling oil according to the present disclosure may exhibit excellent electrical insulation properties.

The coolant for an immersion cooling system according to an embodiment of the present disclosure may further include one or more additives selected from antioxidants, defoamers, and corrosion inhibitors. In the present disclosure, the coolant for the immersion cooling system is also simply referred to as ‘immersion coolant’ or is also referred to as ‘immersion cooling oil composition’ to indicate that one or more additives are mixed with the polyalphaolefin cooling oil.

It is important for the immersion coolant to maintain electrical insulation properties in addition to heat transfer properties. Most of additives lower the electrical insulation properties of the immersion cooling oil composition when being mixed with the immersion cooling oil. Thus, it is desirable to minimize the use amount of the additives and minimize the types of the additives.

Therefore, according to one embodiment of the present disclosure, it is preferable that the polyalphaolefin cooling oil is contained in 99.0 to 99.9% by weight, relative to 100% by a weight of the coolant for the immersion cooling system, and the additive is preferably contained in a small amount of 0.1 to 1.0% by weight, relative to 100% by a weight of the coolant for the immersion cooling system.

The antioxidant acts to react with the radicals produced during the oxidation process in the immersion coolant to inhibit the chain reaction of the radicals. The antioxidant may improve oxidation stability of the PAO cooling oil in a high-temperature environment, thereby improving a service life of the coolant for the immersion cooling system. For example, toluene-based antioxidants, phenol-based antioxidants, etc. may be used as the antioxidant. Specific examples thereof may include butylated hydroxytoluene (BHT), phenol alkyl ester, phenol amine, etc., but are not limited thereto. In order to further increase the oxidation stability, the toluene-based antioxidant, for example, dibutylhydroxytoluene, may be used.

The defoamer serves to weaken the surface tension to suppress the formation of bubbles that may be generated during circulation of the immersion coolant. Specific examples thereof may include, but are not limited to, polyacrylates, polydimethylsiloxane, and bis-(nonylphenyl)amine.

The corrosion inhibitor acts as a reducing agent to prevent oxidation of the metal material in contact with the immersion coolant. For example, a triazole-based corrosion inhibitor may be used. Specific examples thereof may include, but are not limited to, benzotriazole.

Hereinafter, the present disclosure is described in more detail based on Preparation Example and Experimental Example. However, the following Preparation Example and Experimental Example only are merely embodiments of the present disclosure, and the contents of the present disclosure are not limited thereto.

### PREPARATION EXAMPLE

As shown in Table 1 as set forth below, PAO cooling oils with different properties of Present Example 1, and Comparative Examples 1, and 2 were prepared.

TABLE 1

| | Present | Comparative | Comparative |
|---|---|---|---|
| | Example 1 | Example 1 | Example 2 |
| Appearance evaluation | Bright and | Bright and | Bright and |
| | clear | clear | clear |
| Density(@20° C.) [kg/m³] | 796 | 806 | 812 |
| Kinematic viscosity | 5.0 | 10.0 | 20.0 |
| (@40° C.) [cst] | | | |
| Acid number [mg KOH/g] | ≤0.01 | ≤0.01 | ≤0.01 |
| Thermal conductivity(@40° C.) | 0.13 | 0.14 | 0.14 |
| [W/m · K] | | | |
| Specific heat capacity | 2.29 | 2.29 | 2.29 |
| (@40° C.) [kJ/Kg · K] | | | |
| Breakdown voltage [kV] | 40 | 40 | 40 |
| Volume resistivity [Ω · cm] | 1.0 × 10¹³ | 1.0 × 10¹³ | 1.0 × 10¹³ |

As may be identified in Table 1 as set forth above, Present Example 1 exhibited a very low level of the kinematic viscosity, compared to that of each of Comparative Examples 1 and 2. That is, in Present Example 1, a dimer formation reaction rather than a trimer formation reaction or tetramer formation reaction of 1-decene as a raw material (feedstock) was induced in the PAO synthesis, thereby lowering the viscosity of Present Example 1.

### Experimental Example 1

As shown in Table 2 as set forth below, each of antioxidant A (Butylated hydroxytoluene), antioxidant B (phenol alkyl ester), and antioxidant C (Phenol Amine) was mixed with the PAO prepared in Present Example 1 to prepare the immersion cooling oil composition (=immersion coolant) of each of Present Example 2, and Comparative Examples 3 to 5. A service life thereof was evaluated using the ASTM D6186 evaluation method.

The ASTM D6186 evaluation method refers to a method of measuring the time it takes for the oxidation reaction of PAO to start under a harsh condition of high temperature and oxygen supply, and is used as a method of evaluating the service life of the cooling oil. It was identified based on the Table 2 that when the antioxidant was added to the PAO cooling oil to slow down the time it takes for the oxidation reaction of the PAO to start.

TABLE 2

| | | | Present | | Comparative | | Comparative | | Comparativ | |
|---|---|---|---|---|---|---|---|---|---|---|
| | | | Example 2 | | Example3 | | Example 4 | | e Example 5 | |
| Composition | Base Oil | PAO | 99.95 | wt % | 100 | wt % | 99.95 | wt % | 99.95 | wt % |
| | Antioxidant | A | 0.05 | wt % | 0 | | 0 | | 0 | |
| | | B | | | 0 | | 0.05 | wt % | 0 | |
| | | C | | | 0 | | 0 | | 0.05 | wt % |
| Evaluation | ASTM | 180° C. | 20 | min< | 2 | min> | 15 | min< | 10 | min< |

| | |
|---|---|
| method | D6186 |

### Experimental Example 2

As shown in Table 3 as set forth below, immersion cooling oil compositions were respectively prepared with and without adding the defoamer ‘polyacrylate’ to the PAO prepared in Present Example 1, and whether the formation of bubbles occurred therein was evaluated using the ASTM D892 evaluation method.

Continuously circulating fluid such as the immersion cooling oil generates bubbles in the circulating process, and the generated bubbles may apply a load on an apparatus such as a heat exchanger and a pump. The ASTM D892 evaluation method refers to a method of artificially generating the bubbles and measuring the amount of generated bubbles, and re-measuring the amount of bubbles after 30 minutes to evaluate the bubble generation. It was identified that the adding of the defoamer to the PAO cooling oil in accordance with the present disclosure may suppress the formation of bubbles.

TABLE 3

| | | | Present | | Comparative |
|---|---|---|---|---|---|
| | | | Example 3 | | Example6 |
| Composition | Base Oil | PAO | 99.98 | wt % | 100 wt % |
| | Defoamer | Polyacrylate | 0.02 | wt % | 0 |

| | | | | |
|---|---|---|---|---|
| Evaluation | ASTM D892 | Seq 1 | 5/0 | 20/0 |
| method | | Seq 2 | 5/0 | 10/0 |
| | | Seq 3 | 5/0 | 20/0 |

### Experimental Example 3

As shown in Table 4 as set forth below, immersion cooling oil compositions were respectively prepared with and without adding the corrosion inhibitor ‘benzotriazole’ into the PAO prepared in Present Example 1. Corrosion prevention performance thereof was evaluated based on a metal change evaluation result according to ASTM D130 evaluation method.

An electronic product such as the server to which the immersion cooling oil is applied require an anti-corrosion function because the corrosion may cause damage to the product. The ASTM D130 evaluation method refers to a method of immersing a copper metal into a liquid and evaluating metal change due to corrosion. It was identified that the adding of the corrosion inhibitor prevented corrosion.

TABLE 4

| | | | Present | | Comparative | |
|---|---|---|---|---|---|---|
| | | | Example 4 | | Example 7 | |
| Composition | Base Oil | PAO | 99.98 | wt % | 100 | wt % |
| | Corrosion | Benzotriazole | 0.02 | wt % | 0 | wt % |

| | | | | |
|---|---|---|---|---|
| | inhibitor | | | |
| Evaluation | ASTM D130 | (3 hr, 100° C.) | 1a | 1b |
| method | | | | |

### Experimental Example 4

The PAO cooling oil as obtained in each of Present Example 1, Comparative Example 1 and 2 as set forth above was mixed with 0.05% by weight of dibutylhydroxytoluene as the antioxidant, 0.02% by weight of polyacrylate as the defoamer, and 0.02% by weight of benzotriazole as the corrosion inhibitor, such that a final immersion cooling oil composition (a total content of 100% by weight) of each of Present Example 5 and Comparative Examples 8 and 9 was prepared.

It was confirmed that in an environment where the data center server was immersed in the immersion cooling oil composition as prepared above, the CPU load was maintained at 90%, the memory RAM load was maintained at in a range of 10 to 90%, and the server operated normally. At this time, the immersion cooling oil composition was circulated at a predefined flow rate sufficient to sufficiently immerse the data center server therein. When the temperature rises (exceeds 27 to 30° C.), a cooling fan operated to keep the temperature of the immersion cooling oil composition constant. In this state, the performance of the immersion cooling oil composition as the coolant in the data center was evaluated. The evaluation result was shown in Table 5 as set forth below.

TABLE 5

| | | Comparative | Comparative |
|---|---|---|---|
| | | Example 8 | Example 9 |
| | Present Example 5 | (PAO of | (PAO of |
| | (PAO of Present | Comparative | Comparative |
| | Example 1) | Example 1) | Example 2) |
| Coolant average | 35° C. | 35° C. | 35° C. |
| temperature | | | |
| CPU average | 60° C. | 70° C. | 75° C. |
| temperature | | | |
| Cooling power | 0.08 KWh per | 0.14 KWh per | 0.20 Wh per |
| consumption | server | server | server |

As may be identified in Table 5, when using Present Example 5 including the immersion cooling oil composition containing the PAO according to Present Example 1, the average temperature of the CPU was maintained to be lower than that when using each of Comparative Examples 8 and 9 respectively including the PAOs of Comparative Examples 1 and 2. Thus, it is identified that the immersion cooling oil composition (Present Example 5) containing PAO according to Present Example 1 has the excellent cooling effect, and has much lower cooling power consumption than that of the immersion cooling oil composition of each of Comparative Examples 8 and 9, resulting in excellent energy efficiency.

The final immersion cooling oil composition (total content of 100% by weight) was prepared by mixing 0.01% by weight of dibutylhydroxytoluene as the antioxidant with the PAO cooling oil obtained in Present Example 1.

In order to evaluate the actual use stability and lifespan of the immersion cooling oil composition when the immersion cooling oil composition is applied to the data center, the data center server was immersed in the immersion cooling oil composition, and then, the data center server operated for approximately 2,000 hours (12 weeks), and then, changes in the physical properties of the immersion cooling oil were evaluated. The evaluation result is as shown in Table 6 as set forth below. Fourier transform infrared spectroscopy (FT-IR) analysis was performed thereon, and a resulting graph is shown in the FIGURE. The FT-IR analysis method refers to a scheme using the principle that a chemical substance absorbs its own unique infrared wavelength, and that when change occur in the chemical substance, the wavelength absorbed thereby changes.

The main properties of the immersion cooling oil before immersion the data center server therein were compared with the main properties of the immersion cooling oil after immersion in the server therein and then, operation of the server for 2000 hours. The comparing results are shown in Table 6 as set forth below and the FIGURE (graph based on Fourier transform infrared spectroscopy). In the FIGURE, the horizontal axis denotes a wavenumber and the vertical axis denotes absorbance, and the graph is unique depending on a structure and a functional group of the chemical substance. The immersion cooling oil composition according to the present disclosure maintains a unique graph of the chemical substance over time. This means that the immersion cooling oil composition maintains its chemical structure stably even under the server is immersed in the immersion cooling oil composition to cool down the server.

Among the graphs of the FIGURE, the bottommost graph relates to a Fresh Fluid (no time elapse), a next-bottommost graph relates to 1 week (after 1 week), an lower middle graph relates to 2 week (after 2 weeks), a upper middle graphs relates to 4 week (after 4 weeks), a next-uppermost graph relates to 6 week (after 6 weeks), and the uppermost graph relates to 12 week (after 12 weeks).

From the results in Table 6 and the FIGURE, it was identified that there was almost no change in the physical properties before and after the operation of the data center server. As a result, it was identified that the physical properties of the immersion cooling oil composition were maintained stably even when the immersion cooling oil composition was applied to the actual data center server and thus the immersion cooling oil composition had a long service lifespan.

TABLE 6

| | | Used Fluid (after |
|---|---|---|
| | | 12 weeks (approximately |
| | Fresh fluid | 2000 hours)) |
| Appearance evaluation | Bright and clear | Bright and clear |
| Density(@20° C.) [kg/m³] | 796 | 798 |
| Kinematic viscosity | 5 | 5 |
| (@40° C.) [cst] | | |
| Acid number [mg KOH/g] | ≤0.01 | ≤0.01 |
| Thermal conductivity | 0.13 | 0.13 |
| (@40° C.) [W/m · K] | | |
| Specific heat capacity | 2.29 | 2.28 |
| (@40° C.) [kJ/Kg · K] | | |
| Breakdown voltage [kV] | 40 | 40 |
| Volume resistivity [Ω · cm] | 1.0 × 10¹³ | 1.0 × 10¹³ |

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. Coolant for an immersion cooling system, the coolant comprising:
polyalphaolefin (PAO) cooling oil polymerized via oligomerization of C5 to C15 alpha olefin monomers (α-olefin monomers),
wherein the polyalphaolefin cooling oil has:
a kinematic viscosity at 40° C. lower than 10.0 cst;
a density at 20° C. of 800 kg/m³ or lower;
a specific heat capacity at 40° C. of 1.5 kJ/Kg·K or greater; and
a thermal conductivity at 40° C. of 0.10 W/m·k or greater.

2. The coolant for the immersion cooling system of claim 1, wherein a flash point of the polyalphaolefin cooling oil is in a range of 120 to 300° C.

3. The coolant for the immersion cooling system of claim 1, wherein the polyalphaolefin cooling oil is polymerized via oligomerization of C8 to C12 alpha olefin monomers.

4. The coolant for the immersion cooling system of claim 1, wherein an appearance of the polyalphaolefin cooling oil has a bright and clear color.

5. The coolant for the immersion cooling system of claim 1, wherein the coolant for the immersion cooling system further contains at least one additive selected from an antioxidant, a defoamer, and a corrosion inhibitor.

6. The coolant for the immersion cooling system of claim 5, wherein the polyalphaolefin cooling oil is contained at 99.0 to 99.9% by weight based on 100% by weight of the coolant for the immersion cooling system,
wherein the at least one additive is contained at 0.1 to 1.0% by weight based on 100% by weight of the coolant for the immersion cooling system.

7. An immersion cooling system comprising the coolant for the immersion cooling system of claim 1.
